(19) United States
(12) Patent Application Publication
(10) Pub. No.: US 2025/0350285 A1
(43) Pub. Date: Nov. 13, 2025

(54) NOISE DOWN CONVERSION FOR JITTER REDUCTION

(71) Applicant: Silicon Laboratories Inc., Austin, TX (US)

(72) Inventors: Yun Da Bryan Seah, Singapore (SG); Hua Beng Chan, Singapore (SG); Tak Ying Wong, Singapore (SG)

(21) Appl. No.: 18/657,069

(22) Filed: May 7, 2024

(51) Int. Cl. H03L 7/093; H03B 5/12; H03L 7/099

(52) U.S. Cl. CPC H03L 7/093; H03B 5/1228; H03L 7/099

(57) ABSTRACT

A down-sampling function folds the thermal noise into a lower frequency band. A capacitor samples a voltage during a period of bus inactivity and supplies the sampled voltage to an input of operational amplifier in a loop filter of a phase-locked loop when the bus is active. The sampling frequency determines the reduction in thermal noise that can be achieved. The PLL generates a clock signal for a bus. A voltage generator charges the capacitor through a transistor when the bus is inactive. The transistor turns on responsive to the bus being inactive to allow the capacitor to charge and the transistor turns off responsive to the bus being active to isolate the capacitor and operational amplifier from the voltage generator. When the bus is active, the voltage across the capacitor is supplied to the operational amplifier.

### CROSS-REFERENCE TO RELATED APPLICATION(S)

This application is related to U.S. Patent Application No. xx/xxx,xxx (Attorney Docket No. 026-0490), filed the same day as the present application, entitled “CHARGE INJECTION REDUCTION IN A FRACTIONAL-N FREQUENCY SYNTHESIZER,” naming Yun Da Bryan Seah, et al., as inventors, and this application relates to U.S. Patent Application No. xx/xxx,xxx (Attorney Docket No. 026-0492), filed the same day as the present application, entitled “PHASE-LOCKED LOOP WITH IMPROVED PROCESS, FREQUENCY AND TEMPERATURE INDEPENDENCE”, naming Yun Da Bryan Seah et al., as inventors, which applications are hereby incorporated by reference in their entirety.

### BACKGROUND

### Field of the Invention

This invention relates to techniques for lowering thermal noise by down-sampling.

### Description of the Related Art

Synchronous buses such as the Serial Peripheral Interface (SPI) bus provide communication from integrated circuits such as micro controller unit (MCU) integrated circuits to various peripheral devices. The SPI bus includes a clock (SCLK), at least one bidirectional data line (or unidirectional data lines), and a control line (Chip Select) that indicates when the bus is active. Noise on the clock signal can degrade bus performance and increase the chance of bit errors.

### SUMMARY OF EMBODIMENTS OF THE INVENTION

Accordingly, embodiments realize a down-sampling function to fold the thermal noise into a lower frequency band. In an embodiment, a method includes coupling a voltage generator to a capacitor to charge the capacitor during a first time period. The method further includes isolating the voltage generator from the capacitor and from an operational amplifier during a second time period and supplying a voltage from the capacitor to the operational amplifier during the second time period.

In an embodiment the first time period is when a bus is inactive and the second time period is when the bus is active.

In an embodiment the method further includes using the operational amplifier to generate a control signal for an oscillator and supplying a clock signal for the bus based on an output of the oscillator.

In an embodiment the bus is determined to be active responsive to a bus control signal being asserted.

In an embodiment the method further includes turning on a first transistor during the first time period to couple the voltage generator to the capacitor and to an input of the operational amplifier and turning off the transistor during the second time period to isolate the voltage generator from the capacitor and from the input of the operational amplifier.

In another embodiment an apparatus includes an operational amplifier. A voltage generator is coupled to the operational amplifier during a first time period. A capacitor is coupled to a node between the voltage generator and the operational amplifier. The capacitor is coupled to the voltage generator during the first time period and configured to store a sampled voltage and the sampled voltage is supplied to the operational amplifier during a second time period.

In an embodiment the first time period corresponds to a bus being active and the second time period corresponds to the bus being inactive.

In an embodiment the apparatus further includes an oscillator having a control signal coupled to an output of the operational amplifier. A clock signal for the bus is coupled to an output of the oscillator.

In an embodiment the bus is determined to be active responsive to a bus control signal being asserted.

In an embodiment a first transistor is coupled between the voltage generator and the capacitor to couple the voltage generator to the capacitor during the first time period and the first transistor is turned on responsive to the bus being inactive to allow the capacitor charge. The first transistor is turned off responsive to the bus being active to isolate the capacitor from the voltage generator and to cause the sampled voltage to be supplied to the operational amplifier.

In another embodiment an apparatus includes an operational amplifier. A voltage generator is coupled to the operational amplifier during a first time period. A transistor is coupled between the voltage generator and the operational amplifier. A capacitor has a first terminal coupled to a node between the first transistor and the operational amplifier and has a second terminal coupled to ground. The capacitor samples a voltage on the node during the first time period and stores a sampled voltage. The transistor turns on responsive to the bus being inactive to allow the capacitor to charge and the transistor turns off responsive to the bus being active to cause the sampled voltage to be supplied to the operational amplifier and to cause the capacitor and the operational amplifier to be isolated from voltage generator.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a functional block diagram of a fractional-N frequency synthesizer.

FIG. 2 illustrates a functional block diagram showing how the voltage generated by the voltage regulator is sampled by the capacitor and supplied from the capacitor to the operational amplifier.

FIG. 3 illustrates a functional block diagram of a voltage generator.

FIG. 4 illustrates a high level block diagram of a synchronous communication interface used in one or more embodiments.

FIG. 5 is a timing diagram showing the bus chip select signal and the sample control signal that causes the capacitor to sample the voltage from the voltage generator when the bus is inactive.

FIG. 6 is a timing diagram showing Vcm_generated and sampled Vcm_sampled over time.

FIG. 7 illustrates an embodiment of a voltage regulator configured to sample the reference voltage to achieve down sampling.

The use of the same reference symbols in different drawings indicates similar or identical items.

### DETAILED DESCRIPTION

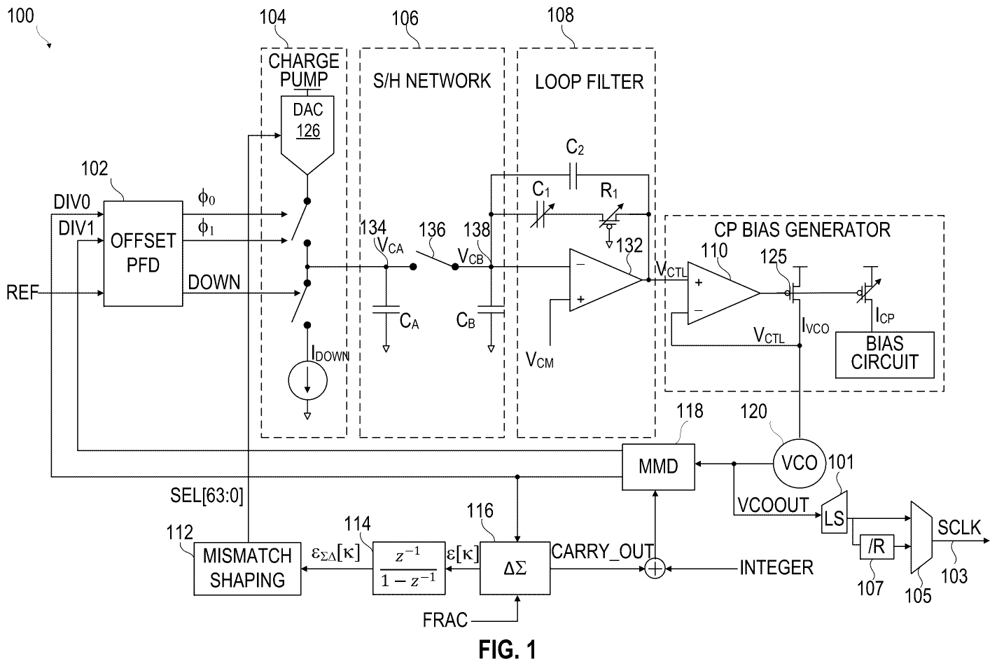

A phase-locked loop (PLL) such as shown in FIG. 1 is often used to generate a clock signal for a synchronous communication interface such as the SCLK for the SPI bus. Communication interfaces that are synchronous in nature can have short and frequent transmissions, e.g., where the peripheral device is a memory. The bursty nature of these bus transmissions allow for re-calibration of the PLL during the bus off time. In an embodiment, recalibration includes recalibrating the common mode voltage (Vcm) used in an operational amplifier in the loop filter of the PLL. In an embodiment the bus off time can be used to recharge a capacitor to hold a sample of the generated voltage. When the bus is active, (e.g., during WRITE/READ), the capacitor holds a sampled voltage and the sampled voltage is used as the common mode voltage supplied to the operational amplifier. Using the sampled voltage ensures that any change in the generated voltage due to changes in voltage or temperature being used by a voltage generator does not propagate to the output of the PLL and cause jitter on the bus clock signal. In the frequency domain, that realizes a down-sampling function, which folds the thermal noise into a lower band, dependent on the frequency of re-sampling. The noise can then be brought out of the bandwidth of interest and thus lead to lowered thermal noise. That lowered thermal noise can lead to improved bus performance due to less noise on the bus clock signal being generated by the PLL, thereby resulting in a lower bit error rate on the bus.

FIG. 1 illustrates an embodiment of a frequency synthesizer implemented as a fractional-N PLL 100 that incorporates the down sampling approach described herein. Of course, other PLL configurations and in fact other circuits can use the down sampling approach described herein to move thermal noise out of the frequency band of interest. Referring to FIG. 1 fractional-N frequency synthesizer 100 generates clock signal VCOOUT having a frequency f_{VCO} that is INTEGER.FRAC times frequency f_{REF} of reference clock signal REF. The multi-modulus divider 118 in combination with the ΔΣ modulator 116 divides the output VCOOUT to have an average frequency determined by the divide ratio INTEGER.FRAC. A level shifter 101 coupled to VCOOUT supplies the SCLK 103 through selector circuit 105. Optionally, the level shifted VCOOUT signal can be divided by an integer R in divider 107 to achieve the desired SCLK frequency. Fractional-N frequency synthesizer 100 includes offset tri-state phase-frequency detector 102, which detects a frequency and phase difference between reference clock signal REF and frequency-divided signals DIV0 and DIV1 and generates pulse control signals (e.g., error cancellation phase signal ϕ₀, full-scale phase signal ϕ₁, and control signal DOWN) based on the frequency and phase difference. Frequency-divided signal DIV0 corresponds to a retimed version of the frequency divided signal DIV, which is clock signal VCOOUT frequency divided by frequency divider value N. Frequency-divided signal DIV1 corresponds to a retimed version of the frequency divided signal DIV delayed by one cycle of clock signal VCOOUT, which is generated by voltage-controlled oscillator 120. In an embodiment, frequency-divided signal DIV0 is generated by a divider-retiming circuit, which may be included in offset tri-state phase-frequency detector 102 or in multi-modulus frequency divider 118. In other embodiments, divider-retiming circuit is excluded and frequency-divided signal DIV0 is clock signal VCOOUT frequency divided by frequency divider value N and frequency-divided signal DIV1 is a version of frequency-divided signal DIV0 that is delayed by one cycle of clock signal VCOOUT.

Offset tri-state phase-frequency detector 102 provides error cancellation phase signal ϕ₀ (or its complementary signal, error cancellation phase signal ϕ_{0b}), full-scale phase signal ϕ₁ (or its complementary signal, error cancellation phase signal ϕ_{1b}), and control signal DOWN to charge pump 104, which implements digital-to-analog conversion and generates an error signal on node 134. To achieve the digital-to-analog conversion functionality, charge pump 104 implements two charge pumps associated with the frequency-divided signals as a shared digital-to-analog converter (DAC) current source that is controlled using select signals SELϕ₀ and SELϕ₁, which are based on a predicted value of fractional phase error ε[k]. The value of fractional phase error ε[k] is based on the residue of the ΔΣ modulator 116 used to dither a divider value, which is consistent with conventional phase interpolation techniques.

Mismatch shaping circuit 112 scrambles the mapping between the residue provided by accumulator 114 and current elements of DAC 126, thereby shaping mismatch-induced noise to high frequencies. The scrambling prevents noise folding of first-order shaped quantization noise. Sample-and-hold network 106 reduces or eliminates the influence of charge pump current pulses on loop filter 108 and VCO 120, thereby reducing or eliminating fractional spurs due to periodic changes in the shape of the current pulses, and reducing the magnitude of a reference spur.

In at least one embodiment, the shape of the charge-pump output waveform changes periodically during steady-state operation. Thus, the output of charge pump 104 contains some residual amount of energy at the fractional spur frequency. In addition, there is significant spurious content at the reference frequency. If charge-pump 104 passes its output directly to loop filter 108, residual fractional spurs and a significant reference spur will result. Instead, sample-and-hold network 106 is included to improve spurious performance of fractional-N frequency synthesizer 100 as compared to other conventional techniques. When at least one current element of charge pump 104 is active, sample switch 136 is open and the current sources of charge pump 104 charge or discharge capacitance C_{A}. When offset tri-state phase-frequency detector 102 and charge pump 104 complete operation, sample switch 136 is closed and op-amp summing junction 138 is coupled to capacitance C_{A}. Under steady-state operation, charge pump 104 transfers zero net charge to capacitance C_{A} over each reference period, ignoring noise. By sampling after offset tri-state phase-frequency detector 102 and charge pump 104 completes operation, charge pump 104 does not transfer any charge to loop filter 108 in steady-state, voltage-controlled oscillator 120 sees no disturbance on its control voltage V_{CTL}, and spurs are reduced or eliminated.

Since the positive terminal of operational amplifier 132 is set to common mode voltage V_{CM} and the negative terminal of operational amplifier 132 is also nominally at common mode voltage V_{CM} (plus or minus any input offset in operational amplifier 132), the nominal voltage at the output of charge-pump 104 is also at common mode voltage V_{CM}. However, voltage V_{CA} at the charge-pump output (e.g., node 134) will fall below common mode voltage V_{CM} during normal operation. Since currents I_{UP} and I_{DOWN} may vary from their corresponding nominal values according to their corresponding output impedances of charge-pump 104, capacitance C_{A} is selected to be large enough to constrain the voltage swing at node 134 so that current source output impedance does not adversely impact performance. Capacitance C_{A} serves as an intermediate charge-transfer reservoir during transient events when a step in phase error causes the error charge magnitude to exceed the output drive capability of operational amplifier 132. The output (V_{CTL}) of operational amplifier 132 is coupled as the control signal for VCO 120 through unity gain buffer 110 and transistor 125.

In an embodiment, the sampling operation is performed using complementary transmission gate switches with charge-balancing dummy devices. Because voltages V_{CA} and V_{CB} on nodes 134 and 138, respectively, settle to V_{CM} every period before sampling is performed, the circuit acts as a constant sampling network, thereby reducing nonlinear effects associated with variable channel resistance in sample switches. In an embodiment, sample-and-hold network 106 is coupled to a differential-to-single-ended converter circuit. In at least one embodiment, the differential-to-single-ended converter has a dynamic topology that does not dissipate static power and generates coincident complementary full-swing output signals that are useful for charge-injection reduction. The coincident complementary full-swing output signals eliminate an extra inverter delay between an output and a complementary output signal that would otherwise cause a phase difference between overlap charge packets delivered through n-type and p-type transistors in transmission gates of switches 136 in sample-and-hold network 106. Coincident switching causes the device overlap capacitance charge injection to be in phase for the n-type and p-type devices of switches 136.

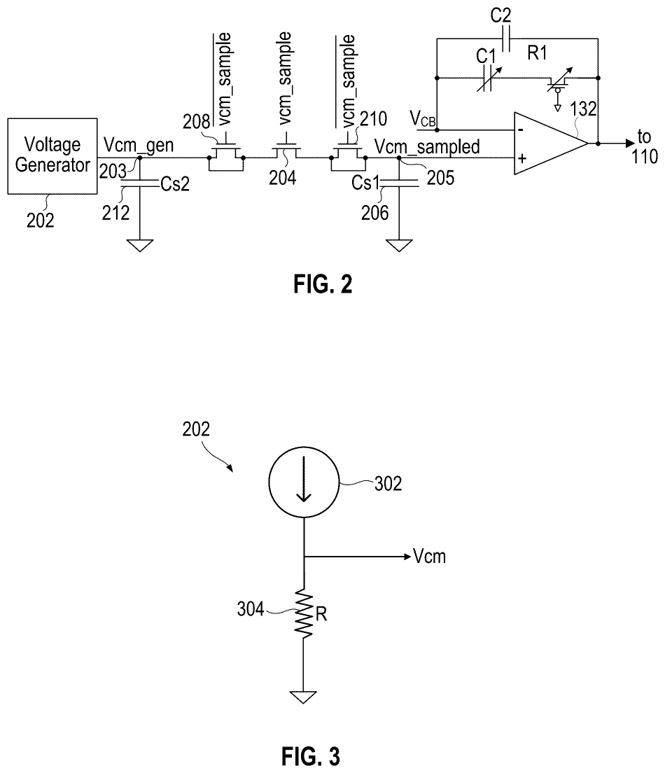

Referring to FIG. 2, voltage generator 202 generates the voltage Vcm_gen that is the basis for the voltage Vcm supplied to the positive input of operational amplifier 132 shown in FIGS. 1 and 2 after being sampled by the capacitor 206. FIG. 3 shows a high level block diagram of an embodiment of the voltage generator 202 that includes a current source 302 supplying a current to resistor 304. The voltage across the resistor is the generated voltage Vcm_gen. Of course, there are many possible ways to implement the voltage generator 202. The voltage generator 202 supplies the voltage Vcm_gen through the transistor 204, which functions as a pass gate, to the node 205. Node 205 is an input to the operational amplifier 132 and one node of capacitor Cs1 206. When the transistor 204 turns on, the sampling capacitor Cs1 206 samples Vcm_gen and stores a voltage Vcm_sampled. When the bus is active, Vcm_sampled is supplied to the operational amplifier 132 as Vcm. Note that the voltage on capacitor Cs1 is slightly below Vcm_gen due to the threshold voltage drop across transistor 204. The dummy transistors 208 and 210 with their drains and sources shorted, serve to mitigate charge injection. The capacitor Cs2 212 charges to the voltage Vcm gen and helps supply voltage to Cs1 when the pass transistor 204 turns on, thereby reducing the voltage droop on Vcm_gen.

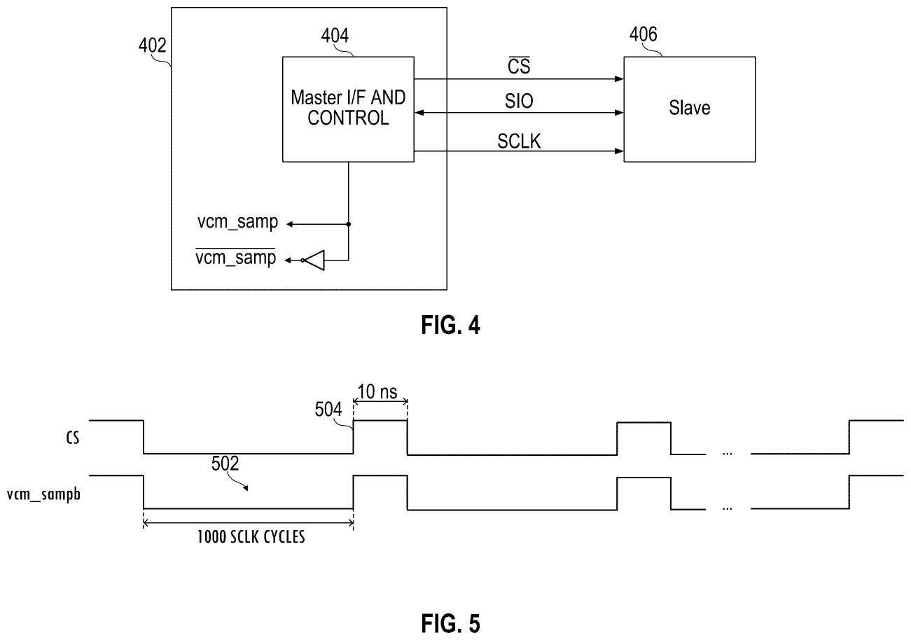

In an embodiment the PLL 100 shown in FIG. 1 generates the clock signal SCLK for the SPI bus illustrated in FIG. 4. FIG. 4 shows Master interface and control circuit 404 on integrated circuit 402, which includes the PLL 100. The control functionality for the SPI Master can be implemented by a combination of control software, hardware, or other appropriate control structures that are well known in the art. The SPI bus is a synchronous bus and often has short and frequenct transmissions. In an embodiment the Slave 406 is a memory. The embodiment of the SPI bus illustrated in FIG. 4 further includes the SCLK signal, the active low chip select (C̅S̅) signal, and the bidirectional Serial Input/Output (SIO) signal to perform data transfers in either direction. The bus is inactive part of the time, allowing re-calibration of certain PLL characteristics during the bus off time. In an embodiment, recalibration recalibrates the common mode voltage (Vcm) supplied to the operational amplifier 132 (see FIGS. 1 and 2) in the loop filter of the PLL 100. In an embodiment the calibration during the bus off time recharges the sample capacitor Cs1 206 (see FIG. 2) using Vcm_gen.

FIG. 5 illustrates use of the C̅S̅ signal on the bus. In an embodiment, the bus is active (C̅S̅ is low) at 502 for a maximum of 1000 SCLK cycles. Of course, other embodiments may have a maximum active time that is longer or shorter. In an embodiment the minimum off time shown at 504 (C̅S̅ is high) is 10 ns. Again, other embodiments may have a different minimum off time. Assuming, e.g., an 80 MHz SCLK, each data bit is transferred in 12.5 ns. Of course, a different implementation, such as a quad implementation with four data bits would have a higher data rate. Referring to FIGS. 2 and 5, when the bus is active indicated by the C̅S̅ being low during, e.g., WRITE/READ, the voltage Vcm_sampled held in the capacitor Cs1 206 is supplied to the operational amplifier as the common mode voltage. The control signal vcm_sample is low when the bus is active (C̅S̅ is low) to turn off transistor 204 and thereby isolate the node 203 from the amplifier 132. That ensures that any change in the generated Vcm voltage due to changes in voltage being used to generate Vcm does not propagate to the output of the PLL. In the frequency domain, that realizes a down-sampling function, which folds the thermal noise into a lower band, dependent on the frequency of re-sampling. The noise can then be brought out of the bandwidth of interest and thus lead to lowered thermal noise. That lowered thermal noise can lead to improved bus performance due to less noise on the bus clock signal being generated by the PLL, thereby resulting in a lower bit error rate on the bus. When the bus is inactive, e.g., at 504, the control signal vcm_sample is high and transistor 204 turns on to recharge capacitor Cs1 206.

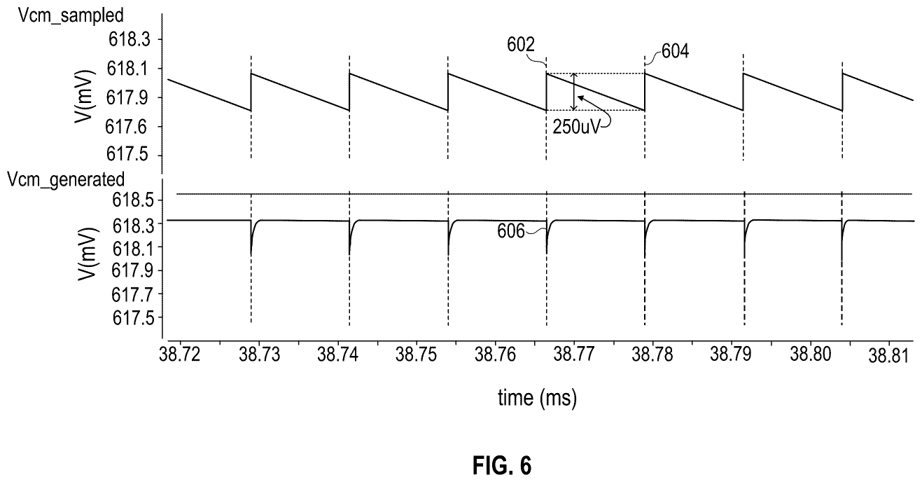

FIG. 6 illustrates voltage waveforms for the voltage Vcm_sampled at node 205 across capacitor Cs1 (see FIG. 2) and the voltage Vcm_gen at node 203 (see FIG. 2). At the beginning of an active bus cycle (C̅S̅=0) at 602 the voltage starts at ˜618.06 mV and drops during the time the bus is active to ˜617.81 mV, which is a drop of ˜250 mV. That 250 mV droop is tolerable in at least some embodiments. If a greater voltage droop is tolerable, the maximum bus active time can be lengthened. If a smaller voltage droop is desired, the maximum bus active time can be reduced to reduce the total droop. At the end of bus being active at 604 the capacitor Cs quickly recharges. Note that while the bus is active, the generated voltage seen at node 203 remains at ˜618.33 mV. When the bus goes inactive, e.g., at 606 there is a voltage droop as the capacitor Cs charges up again. The capacitor 212 (see FIG. 2) is charged to Vcm_generated, and can help reduce the voltage droop at Vcm generated at node 203 when Cs1 is recharged at the beginning of the bus off time.

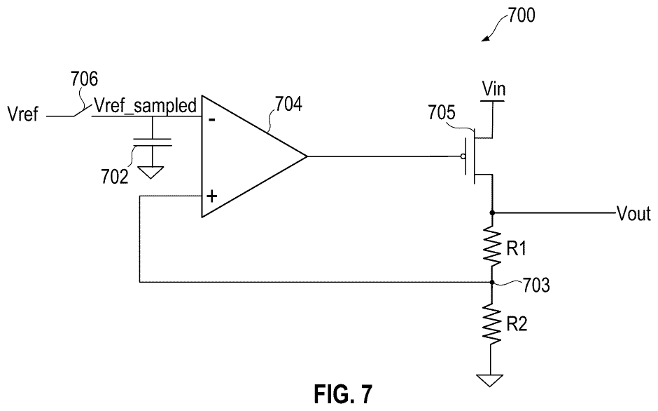

While FIGS. 1 and 2 illustrate an embodiment associated with a PLL, the down-sampling approach described herein can be employed more generally to fold thermal noise into a lower frequency band, dependent on the frequency of re-sampling. FIG. 7 illustrates an embodiment of a voltage regulator 700 that generates a regulated voltage Vout. The reference voltage Vref_gen is periodically sampled by the sampling capacitor 702. The operational amplifier 704 receives the reference voltage Vref_sampled at its negative input and the voltage from node 703, which is indicative of Vout. The amplifier 704 adjusts the gate voltage at transistor 705 based on the difference between Vref_sampled and the voltage at node 703. The capacitor 702 samples the reference voltage Vref_sampled when switch 706 is closed. When switch 706 is open, Vref_sampled is supplied by capacitor 702. The sampling frequency determines the reduction in thermal noise that can be achieved.

Thus, a down-sampling approach has been described to move thermal noise out of a frequency band of interest. The description of the invention set forth herein is illustrative and is not intended to limit the scope of the invention as set forth in the following claims. The terms “first,” “second,” “third,” and so forth, as used in the claims, unless otherwise clear by context, is to distinguish between different items in the claims and do not otherwise indicate or imply any order in time, location, or quality. Variations and modifications of the embodiments disclosed herein may be made based on the description set forth herein, without departing from the scope of the invention as set forth in the following claims.

What is claimed is:

1. A method comprising:
coupling a voltage generator to a capacitor to charge the capacitor during a first time period;
isolating the voltage generator from the capacitor and from an operational amplifier during a second time period; and
supplying a voltage from the capacitor to the operational amplifier during the second time period.

2. The method as recited in claim 1 where the first time period is when a bus is inactive and the second time period is when the bus is active.

3. The method as recited in claim 2 further comprising:
using the operational amplifier to generate a control signal for an oscillator; and
supplying a clock signal for the bus based on an output of the oscillator.

4. The method as recited in claim 2 wherein the bus is determined to be active responsive to a bus control signal being asserted.

5. The method as recited in claim 1 further comprising:
turning on a first transistor during the first time period to couple the voltage generator to the capacitor and to an input of the operational amplifier; and
turning off the transistor during the second time period to isolate the voltage generator from the capacitor and from the input of the operational amplifier.

6. The method as recited in claim 1 wherein the voltage supplied to the operational amplifier is a common mode voltage.

7. The method as recited in claim 1 further comprising charging a second capacitor having a first terminal coupled to a node between the voltage generator and the pass transistor using the voltage generated at the node by the voltage generator.

8. An apparatus comprising:
an operational amplifier;
a voltage generator coupled to the operational amplifier during a first time period;
a capacitor coupled to a node between the voltage generator and the operational amplifier, the capacitor coupled to the voltage generator during the first time period and configured to store a sampled voltage; and
wherein the sampled voltage is supplied to the operational amplifier during a second time period.

9. The apparatus as recited in claim 8 further comprising a voltage regulator including the operational amplifier and wherein the voltage is a reference voltage.

10. The apparatus as recited in claim 8 wherein the first time period corresponds to a bus being active and the second time period corresponds to the bus being inactive.

11. The apparatus as recited in claim 10 further comprising:
an oscillator having a control signal coupled to an output of the operational amplifier; and
wherein a clock signal for the bus is coupled to an output of the oscillator.

12. The apparatus as recited in claim 8 further comprising a phase-locked loop including the oscillator and the operational amplifier.

13. The apparatus as recited in claim 10 wherein the bus is determined to be active responsive to a bus control signal being asserted.

14. The apparatus as recited in claim 10 further comprising:
a first transistor coupled between the voltage generator and the capacitor to couple the voltage generator to the capacitor during the first time period;
wherein the first transistor is turned on responsive to the bus being inactive to allow the capacitor charge; and
wherein the first transistor is turned off responsive to the bus being active to isolate the capacitor from the voltage generator and to cause the sampled voltage to be supplied to the operational amplifier.

15. The apparatus as recited in claim 14 further comprising:
a second transistor coupled in series with the first transistor and disposed between the voltage generator and the first transistor and having its source and drains shorted together;
a third transistor coupled in series with the first transistor and disposed between the first transistor and the capacitor and having its source and drain shorted together; and
wherein the second transistor and the third transistor turn on responsive to the bus being active and turn off responsive to the bus being inactive.

16. The apparatus as recited in claim 8 wherein the voltage is a common mode voltage.

17. The apparatus as recited in claim 8 further comprising a second capacitor having a first terminal coupled to a node between the voltage generator and the first transistor and a second terminal coupled to ground.

18. An apparatus comprising:
an operational amplifier;
a voltage generator coupled to the operational amplifier during a first time period;
a transistor coupled between the voltage generator and the operational amplifier;
a capacitor having a first terminal coupled to a node between the first transistor and the operational amplifier and a second terminal coupled to ground, the capacitor to sample a voltage supplied to the capacitor through the transistor during the first time period and store a sampled voltage;
wherein the transistor turns on responsive to the bus being inactive to allow the capacitor to charge; and
wherein the transistor turns off responsive to the bus being active to the sampled voltage to be supplied to the operational amplifier and to cause the capacitor and operational amplifier to be decoupled from the voltage generator.

19. The apparatus as recited in claim 18 wherein the bus is determined to be active responsive to a bus control signal being asserted and to be inactive responsive to the bus control signal being deasserted.

20. The apparatus as recited in claim 18 further comprising a phase-locked loop (PLL), the PLL including the operational amplifier and the PLL being used to generate a clock signal for the bus.
